(19) United States
(12) Patent Application Publication
(10) Pub. No.: US 2015/0069488 A1
(43) Pub. Date: Mar. 12, 2015

(54) NONVOLATILE SEMICONDUCTOR MEMORY DEVICE

(71) Applicants: Hisakazu MATSUMORI, Yokkaichi (JP); Jun MURAKAMI, Yokkaichi (JP)

(72) Inventors: Hisakazu MATSUMORI, Yokkaichi (JP); Jun MURAKAMI, Yokkaichi (JP)

(21) Appl. No.: 14/187,786

(22) Filed: Feb. 24, 2014

(30) Foreign Application Priority Data
Sep. 6, 2013 (JP) 2013-185034

(51) Int. Cl. H01L 21/28; H01L 29/788; H01L 29/66; H01L 29/40; H01L 27/115

(52) U.S. Cl. CPC H01L 21/28273; H01L 29/401; H01L 27/11531; H01L 29/66825; H01L 29/788
USPC 257/315; 438/587

(57) ABSTRACT

According to one embodiment, a memory cell transistor is obtained by forming a first gate insulating film, a first conductive film of a first conductivity type, a first inter-electrode insulating film, and a second conductive film of the first conductivity type, in this order, and a peripheral transistor which is obtained by forming a second gate insulating film, a third conductive film of the second conductivity type opposite to the first conductivity type, the inter-electrode insulating film, a fourth conductive film in which the first conductivity type dopant is doped, a barrier film, and a fifth conductive film in which the second conductivity type dopant is doped, in which in the peripheral transistor, an opening is formed on the barrier film, the fourth conductive film, and the inter-electrode insulating film, and the fifth conductive film is formed so as to come in contact with the third conductive film through the opening.

### CROSS-REFERENCE TO RELATED APPLICATION

This application is based upon and claims the benefit of priority from Japanese Patent Application No. 2013-185034, filed Sep. 6, 2013, the entire contents of which are incorporated herein by reference.

### FIELD

Embodiments described herein relate generally to a nonvolatile semiconductor memory device.

### BACKGROUND

In a nonvolatile semiconductor memory device such as a NAND-type flash memory, a memory cell transistor is configured by laminating a gate insulating film, a floating gate electrode film, an inter-electrode insulating film, and a control gate electrode film on a semiconductor substrate. In this case, in the transistor used for a peripheral circuit, a laminating configuration of each film is set in the same manner as the memory cell transistor, and the inter-electrode insulating film is opened to short the floating gate electrode film and the control gate electrode film.

However, a heat treatment step is typically performed after forming the opening in the inter-electrode insulating film during the manufacturing process used to form the semiconductor device. Depending on combination of dopant conductivity types of a floating gate electrode and a control gate electrode, during the heat treatment step, dopants having different conductivity types are mixed within or near the formed opening, and a resistance value of a control gate in the vicinity of the formed opening can be increased.

### DESCRIPTION OF THE DRAWINGS

FIG. 1 is an example of a view schematically showing an electrical configuration of a NAND-type flash memory device of a first embodiment.

FIG. 2A is an example of a memory cell region and FIG. 2B is an example of a schematic plan view of a transistor in a peripheral circuit region.

FIG. 3A is an example of a schematic longitudinal cross-sectional view of a part taken along line A-A of FIG. 2A and FIG. 3B is an example of a schematic longitudinal cross-sectional view of a part taken along line B-B of FIG. 2B.

FIG. 4A is an example of a schematic longitudinal cross-sectional view of a part taken along line A-A of FIG. 2A in one stage of a manufacturing step and FIG. 4B is an example of a schematic longitudinal cross-sectional view of a part taken along line B-B of FIG. 2B.

FIG. 5A is an example of a schematic longitudinal cross-sectional view of a part taken along line A-A of FIG. 2A in one stage of a manufacturing step and FIG. 5B is an example of a schematic longitudinal cross-sectional view of a part taken along line B-B of FIG. 2B.

FIG. 6A is an example of a schematic longitudinal cross-sectional view of a part taken along line A-A of FIG. 2A in one stage of a manufacturing step and FIG. 6B is an example of a schematic longitudinal cross-sectional view of a part taken along line B-B of FIG. 2B.

FIG. 7A is an example of a schematic longitudinal cross-sectional view of a part taken along line A-A of FIG. 2A in one stage of a manufacturing step and FIG. 7B is an example of a schematic longitudinal cross-sectional view of a part taken along line B-B of FIG. 2B.

FIG. 8A is an example of a schematic longitudinal cross-sectional view of a part taken along line A-A of FIG. 2A in one stage of a manufacturing step and FIG. 8B is an example of a schematic longitudinal cross-sectional view of a part taken along line B-B of FIG. 2B.

FIG. 9A is an example of a schematic longitudinal cross-sectional view of a part taken along line A-A of FIG. 2A in one stage of a manufacturing step and FIG. 9B is an example of a schematic longitudinal cross-sectional view of a part taken along line B-B of FIG. 2B.

FIG. 10A is an example of a schematic longitudinal cross-sectional view of a part taken along line A-A of FIG. 2A in a second embodiment and FIG. 10B is an example of a schematic longitudinal cross-sectional view of a part taken along line B-B of FIG. 2B.

FIG. 11A is an example of a schematic longitudinal cross-sectional view of a part taken along line A-A of FIG. 2A in a third embodiment and FIG. 11B is an example of a schematic longitudinal cross-sectional view of a part taken along line B-B of FIG. 2B.

FIG. 12A is an example of a schematic longitudinal cross-sectional view of a part taken along line A-A of FIG. 2A in one stage of a manufacturing step and FIG. 12B is an example of a schematic longitudinal cross-sectional view of a part taken along line B-B of FIG. 2B.

FIG. 13A is an example of a schematic longitudinal cross-sectional view of a part taken along line A-A of FIG. 2A in one stage of a manufacturing step and FIG. 13B is an example of a schematic longitudinal cross-sectional view of a part taken along line B-B of FIG. 2B.

FIG. 14A is an example of a schematic longitudinal cross-sectional view of a part taken along line A-A of FIG. 2A in one stage of a manufacturing step and FIG. 14B is an example of a schematic longitudinal cross-sectional view of a part taken along line B-B of FIG. 2B.

### DETAILED DESCRIPTION

Embodiments of the disclosure may provide a nonvolatile semiconductor memory device that has improved electrical properties.

In general, according to one embodiment, there is provided a nonvolatile semiconductor memory device including a memory cell transistor and a peripheral circuit transistor, the memory cell transistor comprising a first conductive film disposed over a first region of a substrate and comprising a first conductivity type dopant, an inter-electrode insulating film disposed on the first conductive film, and a second conductive film disposed on the inter-electrode insulating film and comprising the first conductivity type dopant, and a peripheral circuit transistor comprising a third conductive film disposed over a second region of the substrate, and comprising a second conductivity type dopant, which is a type opposite to the first conductivity type, the inter-electrode insulating film which is disposed on the third conductive film, a fourth conductive film disposed on the inter-electrode insulating film, and comprising the first conductivity type dopant, a barrier film disposed on the fourth conductive film, and a fifth conductive film disposed on the barrier film, and comprising the second conductivity type dopant. The peripheral circuit transistor includes an opening is formed through a portion of the barrier film, the fourth conductive film, and the inter-electrode insulating film, that exposes the third conductive film, and the fifth conductive film is formed so as to come in contact with the third conductive film within the opening.

Hereinafter, exemplary embodiments applied to a NAND-type flash memory device will be described with reference to the drawings. The drawings are schematically shown and a relationship between a thickness and planar dimensions, a ratio of a thickness of each layer, and the like do not necessarily coincide with actual values. In addition, upward, downward, right, and left directions indicate relative directions when a circuit forming surface side of a semiconductor substrate which will be described later is set to an upper side, and do not necessarily coincide with examples having a gravity acceleration direction as a reference.

### First Embodiment

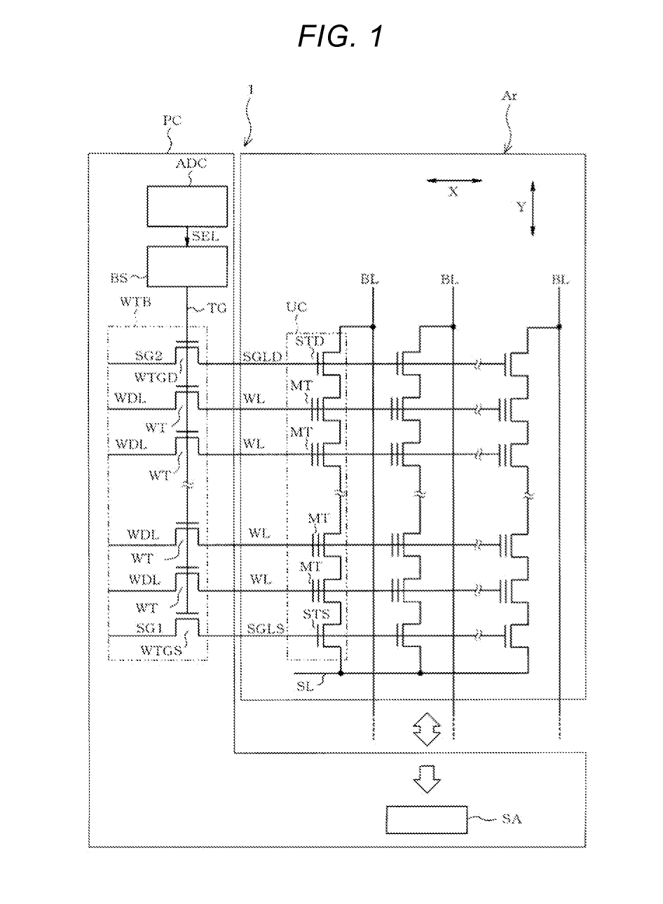

Hereinafter, at least one embodiment will be described with reference to FIG. 1 to FIG. 9B.

FIG. 1 is an example schematically showing an electrical configuration of a NAND-type flash memory device in a block diagram form. As shown in FIG. 1, a NAND-type flash memory device 1 includes a memory cell array Ar in which a plurality of memory cells are arranged in a matrix pattern, a peripheral circuit PC which performs read-out, writing, and deleting of information stored in each memory cell of the memory cell array Ar, an input and output interface circuit (not shown), and the like.

A plurality of cell units UC are arranged in the memory cell array Ar in a memory cell region. In the cell unit UC, a selection gate transistor STD, which is connected to a bit line BL side, a selection gate transistor STS, which is connected to a source line SL side, and a plurality of memory cell transistors MT (e.g., k-th power of 2 transistors, for example, 32 memory cell transistors MT) which are provided between the two selection gate transistors STD and STS, are connected in series.

In one block, n cell units UC are arranged in parallel with each other in an X direction (e.g., row direction: right and left direction in FIG. 1). In the memory cell array Ar, the plurality of blocks are arranged in a Y direction (e.g., column direction: up and down direction in FIG. 1). For simplification of the description, one block is shown in FIG. 1.

A peripheral circuit region is provided in a periphery of the memory cell region, and the peripheral circuit PC is disposed in the periphery of the memory cell array Ar. The peripheral circuit PC includes an address decoder ADC, a sense amplifier SA, a boosting circuit BS including a charge pump circuit, a transfer transistor unit WTB, and the like. The address decoder ADC is electrically connected to the transfer transistor unit WTB through the boosting circuit BS.

The address decoder ADC selects one block according to an address signal applied from an external portion. The boosting circuit BS boosts a driving voltage, which is supplied from an external portion when a selection signal of a block is applied, and supplies a predetermined voltage to each of transfer gate transistors WTGD, WTGS, and WT through a transfer gate line TG.

The transfer transistor unit WTB includes the transfer gate transistor WTGD, the transfer gate transistor WTGS, the word line transfer gate transistor WT, and the like. A transfer transistor unit WTB is provided corresponding to each block.

One of a drain and a source of the transfer gate transistor WTGD is connected to a selection gate driver line SG2 and the other one thereof is connected to a selection gate line SGLD. One of a drain and a source of the transfer gate transistor WTGS is connected to a selection gate driver line SG1 and the other one thereof is connected to a selection gate line SGLS. In addition, one of a drain and a source of the transfer gate transistor WT is connected to a word line driving signal line WDL and the other one thereof is connected to a word line WL which is provided in the memory cell array Ar.

In the plurality of cell units UC which are arranged in the X direction, gate electrodes SG of the selection gate transistors STD are electrically connected to each other by the selection gate line SGLD. In the same manner as described above, the gate electrodes SG of the selection gate transistors STS are electrically connected to each other by the selection gate line SGLS. Sources of the selection gate transistors STS are commonly connected to the source line SL. Gate electrodes MG of the memory cell transistors MT in the plurality of cell units UC which are arranged in the X direction are electrically connected to each other by the word line WL.

Gate electrodes of the transfer gate transistors WTGD, WTGS, and WT are commonly connected to each other by the transfer gate line TG, and are connected to a boosting voltage supply terminal of the boosting circuit BS. The sense amplifier SA is connected to the bit line BL and is connected to a latch circuit which temporarily stores data when reading out the data.

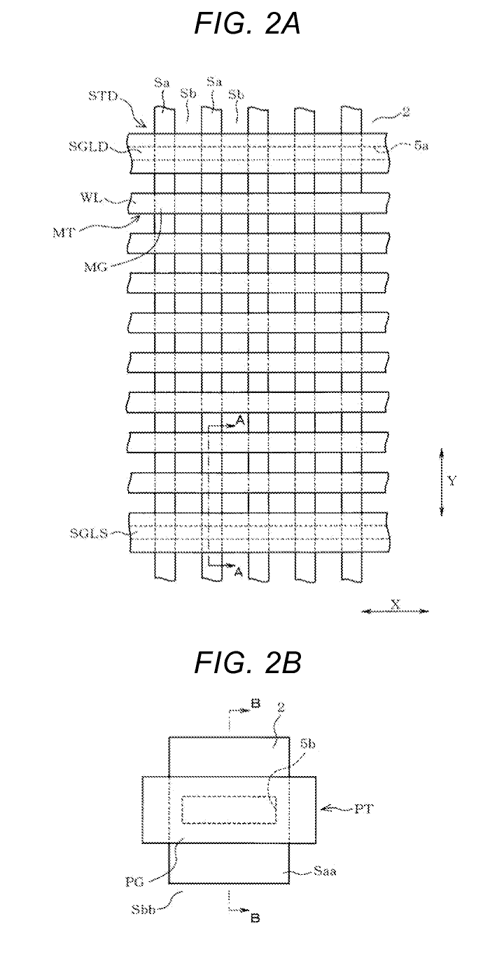

FIG. 2A is one example of a layout pattern of a portion of the memory cell region. As shown in FIG. 2A, in the memory cell region of a silicon substrate 2, which may be a semiconductor substrate, an element isolation area Sb having a shallow trench isolation (STI) structure, in which an insulating film is embedded in a trench, is formed to extend along a Y direction in FIG. 2A. The plurality of element isolation areas Sb are formed at predetermined intervals in the X direction in FIG. 2A. Accordingly, an element region Sa is formed to extend along the Y direction in FIG. 2A, and the plurality of element regions Sa are formed to be separated in the X direction, on a surface layer portion of the silicon substrate 2.

The word line WL is formed to extend along a direction (X direction in FIG. 2A), which is at an angle to (e.g., orthogonal to) and intersects with the element region Sa. The plurality of word lines WL are formed at predetermined intervals in the Y direction in FIG. 2A. The gate electrode MG of the memory cell transistor MT is formed on the upper portion of the element region Sa, which intersects with the word line WL.

The plurality of memory cell transistors MT are adjacent to each other in the Y direction are a part of a NAND column. The selection gate transistors ST (STD and STS) are provided to be adjacent to both outer sides, in the Y direction, of the memory cell transistors MT on both end portions of the NAND column. The plurality of the selection gate transistors ST are provided in the X direction, and the gate electrodes SG of the plurality of selection gate transistors ST are electrically connected to each other through the selection gate line SGL. The gate electrode SG of the selection gate transistor ST is formed on the element region Sa, which intersects with the selection gate line SGL.

FIG. 2B illustrates an example of a layout of a transistor PT of the peripheral circuit. An element isolation area Sbb is formed on the silicon substrate 2 so that a rectangular active region Saa remains. A transistor TrP formed in the peripheral circuit is provided in this rectangular active region Saa. An isolated gate electrode PG is formed in the active region Saa so as to cross the active region, and source and drain regions, which are formed by diffusing dopants therein, are provided on both sides thereof.

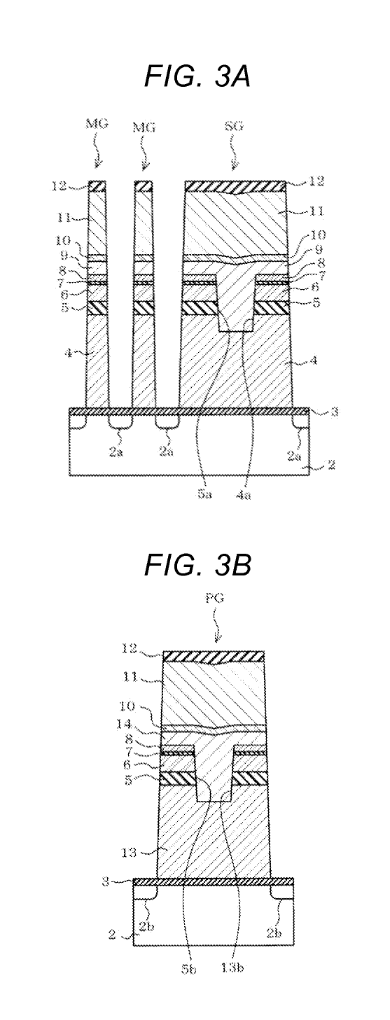

FIGS. 3A and 3B schematically show an example of a cross-sectional structure of an element configuration of the memory cell region and the peripheral circuit, respectively. FIG. 3A is a longitudinal cross-sectional view of a portion of the memory cell transistor MT and the selection gate transistor ST taken along line A-A of FIG. 2A. FIG. 3B is a longitudinal cross-sectional view of the transistor PT of the peripheral circuit of a part taken along line B-B of FIG. 2B. FIGS. 3A and 3B show a state after performing the processing of separating each gate electrode of the memory cell transistor MT, the selection gate transistor ST and the transistor PT.

In FIG. 3A, agate insulating film (first gate insulating film) 3 which may be formed of a silicon oxide film and the like is formed on the upper surface of the silicon substrate 2. The gate electrode MG of the memory cell transistor MT and the gate electrode SG of the selection gate transistor ST are formed on the upper surface of the gate insulating film 3, at the predetermined interval. The memory cell transistor MT includes the gate electrode MG and source and drain regions, which are formed on the gate insulating film 3 and both sides of the silicon substrate 2. The memory cell transistors MT are formed to be adjacent to each other in the Y direction (see FIG. 2A).

The selection gate transistor ST is disposed to be adjacent to the memory cell transistor MT, which is disposed on the end portion. The selection gate transistor ST of the block, which is adjacent to a side opposite to the gate electrode MG of the memory cell transistor MT, is formed on the gate electrode SG of the selection gate transistor ST shown in the drawing, at the predetermined interval. A bit line contact can be formed on a side of a drain region 2a between the two adjacent selection gate transistors ST.

The gate electrode MG of the memory cell transistor MT is obtained by laminating a polycrystalline silicon film 4, an inter-electrode insulating film 5, a polycrystalline silicon film 6, a silicon oxide layer 7, a polycrystalline silicon film 8, a polycrystalline silicon film 9, a tungsten nitride (WN) film 10, a tungsten (W) film 11, and a silicon nitride film 12, in this order, above the gate insulating film 3.

Herein, for the gate insulating film 3, a silicon oxide film (SiO₂) which is formed by performing oxidation treatment of an upper portion of the silicon substrate 2, a silicon oxynitride film (SiNO) which is formed by performing oxynitride treatment thereof, a silicon nitride film (SiN) which is formed by performing nitride treatment, or a laminated film with two or more from these films, may be used. The polycrystalline silicon film 4 is formed as a first conductive film, and functions as the floating gate electrode in the memory cell transistor MT. Boron (B) is doped as a dopant, for example, and the polycrystalline silicon film 4 is formed in a P-type (first conductivity type) as a conductivity type of the semiconductor. For the inter-electrode insulating film 5, an oxide-nitride-oxide (ONO) film or a nitride-oxide-nitride-oxide-nitride (NONON) film, or an insulating film having high permittivity is used.

The polycrystalline silicon film 6 is formed as a second conductive film. The polycrystalline silicon film 6 functions as a part of a control gate electrode in the memory cell transistor MT. Boron (B) is doped as a dopant, for example, and the polycrystalline silicon film 6 has a P-type (first conductivity type) conductivity.

The silicon oxide layer 7 is a layer of a silicon oxide film (SiO₂) formed by performing oxidation treatment of the upper surface of the polycrystalline silicon film 6. The silicon oxide layer 7 has a function of suppressing invasion of boron (B), which is the dopant doped in the polycrystalline silicon film 6 to a side of the polycrystalline silicon films 8 and 9 on the upper layer. The silicon oxide layer 7 can be formed to have a film thickness in a range of not degrading the electrical property of the memory cell transistor MT. For example, the film thickness of the silicon oxide layer 7 can be set thinner than the film thickness of the polycrystalline silicon film 6. The polycrystalline silicon film 8 is formed as a non-doped film in which a dopant is not doped, and with the silicon oxide layer 7 functions as a barrier film. In addition, the polycrystalline silicon film 8 also functions as a protection layer.

The polycrystalline silicon film 9 functions as a part of the control gate electrode in the memory cell transistor MT. In addition, the polycrystalline silicon film 9 is formed as a non-doped film in which a dopant is not doped.

The tungsten nitride (WN) film 10 functions as a barrier metal film of the tungsten (W) film 11, which is formed on the upper surface of the tungsten nitride (WN) film 10. The polycrystalline silicon films 6, 8, and 9, the tungsten nitride film 10 and the tungsten film 11, which are formed on the upper portion of the inter-electrode insulating film 5, function as the control gate electrode and the word line.

Next, the gate electrode SG of the selection gate transistor ST, which is disposed to be adjacent to the gate electrode MG of the memory cell transistor MT, will be described. The gate electrode SG has the same film configuration as the gate electrode MG of the memory cell transistor MT. That is, the polycrystalline silicon film 4 (first conductive film), the inter-electrode insulating film 5, the polycrystalline silicon film 6 (second conductive film), the silicon oxide layer (barrier film) 7, the polycrystalline silicon film (barrier film, protective film) 8, the polycrystalline silicon film 9, the tungsten nitride (WN) film 10, the tungsten (W) film 11, and the silicon nitride film 12 are laminated in this order on the gate insulating film (first gate insulating film) 3 which is formed on the silicon substrate 2. In one embodiment, the inter-electrode insulating film 5 is not formed within the selection gate transistor ST region of the formed device. In other words, the gate electrode SG may include the polycrystalline silicon film 4 (first conductive film), the polycrystalline silicon film 6 (second conductive film), the silicon oxide layer (barrier film) 7, the polycrystalline silicon film (barrier film, protective film) 8, the polycrystalline silicon film 9, the tungsten nitride (WN) film 10, the tungsten (W) film 11, and the silicon nitride film 12 are laminated in this order on the gate insulating film (first gate insulating film) 3 which is formed above the silicon substrate 2.

In the gate electrode SG having the configuration described above, an opening 5a having a predetermined width dimension in a center portion is formed in the inter-electrode insulating film 5, the polycrystalline silicon film 6, the silicon oxide layer 7, and the polycrystalline silicon film 8. A recess 4a is formed on the upper surface portion of the polycrystalline silicon film 4 which is at the same position as the opening 5a. The polycrystalline silicon film 9 is formed so as to bury the inside of the opening 5a and the recess 4a and is electrically connected to the polycrystalline silicon film 4.

A floating gate electrode is not needed in the selection gate transistor ST. Accordingly, the polycrystalline silicon film 8, which serves as the control gate electrode by contacting with the polycrystalline silicon film 4 across the surface of the recess 4a, and accordingly is shorted to the polycrystalline silicon film 4. In this case, if a depth of the recess 4a is large, an area with which the polycrystalline silicon films 8 and 4 come in contact is increased, and therefore it is possible to suppress an increase in contact resistance between the polycrystalline silicon film 8 and the polycrystalline silicon film 4. When the contact resistance is low with respect to a target resistance value, the upper surface of the polycrystalline silicon film 4 can be formed in a substantially flat state, by setting the recess 4a to be shallow or without substantially forming the recess 4a.

In a surface portion of the silicon substrate 2, source and drain regions 2a, which are formed by doping a dopant are provided between the gate electrodes MG and MG, between the gate electrodes SG and MG, and between the gate electrodes SG and SG (portion on a right side of gate electrode SG in FIG. 3A).

Next, a configuration of the gate electrode PG of the transistor PT of the peripheral circuit will be described with reference to FIG. 3B. The gate insulating film (second gate insulating film) 3 is formed above the element formation region Saa of the silicon substrate 2. There are various types of the transistor PT, which may be provided in the peripheral circuit region, and the transistors include a high breakdown voltage transistor and a low breakdown voltage transistor, in a viewpoint of electrical voltage, for example.

The gate insulating film 3 can be formed to have a different film thickness depending on the breakdown voltage of the transistor PT. If the breakdown voltage of the transistor PT is high, the gate insulating film having a large film thickness can be formed, and if the breakdown voltage thereof is low, the gate insulating film having a small film thickness can be formed. In the embodiment as shown in FIG. 3B, the gate insulating film 3 having the same film thickness as the gate insulating film 3 of the memory cell transistor MT or the selection gate transistor ST is formed. The gate electrode PG of the transistor PT in the peripheral circuit region is formed on the gate insulating film 3.

In the gate electrode PG, a polycrystalline silicon film (third conductive film) 13, the inter-electrode insulating film 5, the polycrystalline silicon film (fourth conductive film) 6, the silicon oxide layer (barrier film) 7, the polycrystalline silicon film (barrier film, protective film) 8, a polycrystalline silicon film (fifth conductive film) 14, the tungsten nitride film (WN) 10, the tungsten (W) film 11, and the silicon nitride film 12 are laminated on the gate insulating film 3.

In the configuration described above, the polycrystalline silicon film 13 is formed as a third conductive film. Phosphorus (P) is doped as a dopant, for example, and the polycrystalline silicon film has N-type (second conductivity type) conductivity. The polycrystalline silicon film 13 is formed so as to have conductivity different from that of the polycrystalline silicon film 4 of the memory cell transistor MT, and has N-type conductivity in which phosphorus (P) is doped as a dopant, for example.

The polycrystalline silicon film 6 is formed as a fourth conductive film, and is the same film as the polycrystalline silicon film 6 formed in the memory cell region. Boron (B) is doped as a dopant, and the polycrystalline silicon film 6 has P-type (first conductivity type) conductivity. In substantially the same manner as the silicon oxide layer formed in the memory cell region, the silicon oxide layer 7 is a layer of a thin silicon oxide film (SiO₂), which may be formed by performing oxidation treatment on the upper surface of the polycrystalline silicon film 6.

In the same manner as described above, the polycrystalline silicon film 8 is formed as a non-doped film in which a dopant is not doped, and thus functions as a barrier layer with the silicon oxide layer 7. The polycrystalline silicon film 8 also functions as a protection layer. The polycrystalline silicon film 14 is formed as a fifth conductive film, and phosphorus (P) is doped as an N-type dopant. The configurations of the other films may be the same as those of the gate electrodes MG and SG.

In the gate electrode PG having the configuration described above, an opening 5b having a predetermined width dimension in a center portion is formed in the inter-electrode insulating film 5, the polycrystalline silicon film 6, the silicon oxide layer 7, and the polycrystalline silicon film 8. A recess 13b is formed on the upper surface portion of the polycrystalline silicon film 13, which is at the same position as the opening 5b. The polycrystalline silicon film 14 is formed so as to bury the inside of the opening 5b and the recess 13b and is electrically connected to the polycrystalline silicon film 13.

A floating gate electrode is not needed even in the transistor PT of the peripheral circuit in the same manner as the selection gate transistor ST. Accordingly, the polycrystalline silicon film 14 which serves as the control gate electrode is in contact with the polycrystalline silicon film 13 through the surface of the recess 13b of the opening 5b, and thus electrically connects the polycrystalline silicon film 14 and the polycrystalline silicon film 13. In this case, if a depth of the recess 13b is large, an area with which the polycrystalline silicon films 14 and 13 come in contact is increased, and therefore it is possible to suppress an increase in the contact resistance between the polycrystalline silicon film 14 and the polycrystalline silicon film 13. When the contact resistance is low with respect to a desired resistance value, which is a target value, the upper surface of the polycrystalline silicon film 13 can be formed in a substantially flat state, by setting the recess 13b to be shallow or without substantially forming the recess 13b.

In the configuration described above, an N-type polycrystalline silicon film is formed as a conductive film of a floating gate electrode in some cases. However, herein, by considering the property of the memory cell transistor MT, a configuration where a P-type polycrystalline silicon film is formed as an electrode film of a floating gate electrode is employed. Meanwhile, in the transistor PT of the peripheral circuit, the N-type polycrystalline silicon film 13 is used, which is different from the conductivity type of the polycrystalline silicon film 9 for a floating gate electrode, which is formed at the same time. This is because a change in the properties of the transistor is needed when the channel type is changed, such as a buried channel to a surface channel or vice versa. For example, a transistor that was originally designed to be a surface channel, and then is redesigned to be a buried channel, will require a significant amount of time to rework to readjust characteristics of the redesigned transistor. As described above, it is not necessary to change the design of the transistor PT of the peripheral circuit.

That is, in the transistor PT of the peripheral circuit, since the polycrystalline silicon film 13 of the gate electrode PG is doped to be an N-type and the polycrystalline silicon film 14 which is electrically connected thereto is also formed to be an N-type. It is possible to suppress increasing the contact resistance of the polycrystalline silicon film 13 and the polycrystalline silicon film 14, because pn-junction is not formed between the polycrystalline silicon film 13 and the polycrystalline silicon film 14. The polycrystalline silicon film 6 is not needed in the selection gate transistor ST and the transistor PT of the peripheral circuit, however, for simplification of the manufacturing steps, the polycrystalline silicon film 6 in which a P-type dopant is doped is included in the same manner as the gate electrode MG of the memory cell transistor MT. Accordingly, the dopant in the polycrystalline silicon film 6 may diffuse through the upper surface of polycrystalline silicon film 6 and into the polycrystalline silicon film 14 during an intermediate heat treatment step. However, by providing the silicon oxide layer 7 and/or the non-doped polycrystalline silicon film 8, it is possible to suppress the diffusion of the dopant from the polycrystalline silicon film 6 into the polycrystalline silicon film 14. The polycrystalline silicon film 8 is provided on the lower surface of the polycrystalline silicon film 14. Accordingly, a grain boundary region which is in a boundary portion of the polycrystalline silicon film 8 and the polycrystalline silicon film 14 can suppress the passage of the dopant. As a result, it is possible to suppress a decrease in P-type dopant concentration in a portion used to bury the opening 5b of the polycrystalline silicon film 14 and the recess 14b, and possible to suppress an increase in the resistance value.

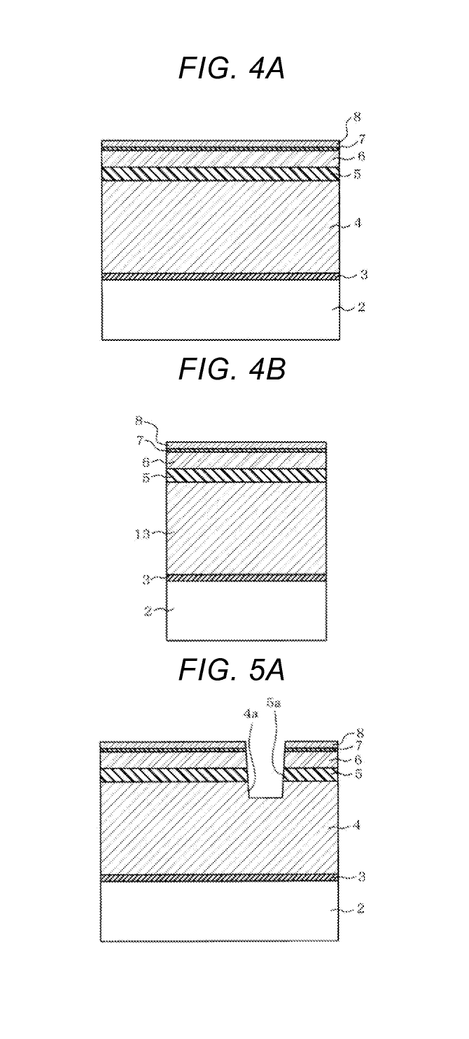

Next, one example of a manufacturing process used to form the configuration(s) shown in FIGS. 3A and 3B will be described with reference to FIG. 4A to FIG. 9B. FIG. 4A to FIG. 9B include diagrams showing one example of the device cross-sectioned at the same position as shown in FIGS. 3A and 3B. The embodiment will be described by focusing on a characterized portion, however, other steps may be added between each step and a step can also be removed. In addition, each of the steps may be appropriately switched as long as it can be practically performed.

In FIG. 4A illustrates a cross section of the memory cell region and FIG. 4B illustrates a cross section of the transistor PT of the peripheral circuit. As illustrated, a silicon oxide film having a predetermined film thickness is formed on the upper surface of the silicon substrate 2 as the gate insulating film 3, by using a thermal oxidation method or the like. Then, a non-doped polycrystalline silicon film is formed on the upper surface of the gate insulating film 3.

A dopant is doped in the non-doped polycrystalline silicon film as follows. First, boron (B) is doped in the polycrystalline silicon film in the memory cell region as a P-type dopant to form a P-type polycrystalline silicon film 4. In addition, phosphorus (P) is doped in the polycrystalline silicon film in the peripheral circuit region as an N-type dopant to form the N-type polycrystalline silicon film 13. In this case, the doping of the dopant may be performed by ion implantation. At this time, owing to selective doping of the dopant(s), the region which is not to be doped can be separated by performing masking with a resist film or the like using one or more lithography technique(s).

Meanwhile, the polycrystalline silicon films 4 and 13 may be formed at two separate times. That is, the polycrystalline silicon film 4 in which the P-type dopant is doped is formed on the entire surface, and the polycrystalline silicon film 4 in the portion of the peripheral circuit is removed. Next, the polycrystalline silicon film 13 in which the N-type dopant is doped is formed on the entire surface, and then the polycrystalline silicon film 13 in the portion of the memory cell region is removed to separate the polycrystalline silicon films.

After that, although not shown in the drawings, silicon nitride films for a hard mask are formed on the upper surfaces of the polycrystalline silicon films 4 and 13, an element isolation groove is formed by etching the polycrystalline silicon films 4 and 13 and the gate insulating film 3 and also etching the silicon substrate 2 to a predetermined depth. The element isolation area Sb is formed by burying an element isolation insulating film in the element isolation groove, and accordingly the element formation region Sa is formed on an upper portion of the silicon substrate 2. In this step, the element isolation area Sbb in the peripheral circuit region is formed at the same time, and accordingly the element formation region Saa is formed on the upper portion of silicon substrate 2. There is no change in the shape of the portions shown in FIGS. 4A and 4B by the formation of the element isolation area Sb.

Next, the inter-electrode insulating film 5 is formed on the upper surface of the polycrystalline silicon film 4 and 13. As described above, an ONO film or a NONON film may be used as the inter-electrode insulating film 5. Subsequently, the polycrystalline silicon film 6 in which boron (B) is doped as a P-type dopant is formed with a predetermined film thickness, so as to cover the upper surfaces of the inter-electrode insulating film 5 and the element isolation insulating film Sb.

Then, by exposing the polycrystalline silicon film 6 to an oxygen atmosphere, the surface portion of the polycrystalline silicon film 6 is oxidized to form the silicon oxide layer 7. In addition, the non-doped polycrystalline silicon film 8 is formed on the upper surface thereof with a predetermined film thickness. For example, the film thickness of the polycrystalline silicon film 6 may be 10 nm to 20 nm and the film thickness of the polycrystalline silicon film 8 may be 5 nm to 10 nm. The silicon oxide layer 7 can be an oxide layer having a thickness of 1 nm to 2 nm, for example. The formation of the polycrystalline silicon film 6, the silicon oxide layer 7, and the polycrystalline silicon film 8 can be continuously and/or sequentially performed in the same chamber.

In the case described above, a silicon nitride layer may be provided by performing a nitridization, instead of forming the silicon oxide layer 7. In addition, instead of performing the oxidization, a process which forms an extremely thin oxide film can be performed to form the silicon oxide layer 7. The silicon oxide layer 7 and the polycrystalline silicon film 8 function as a barrier film.

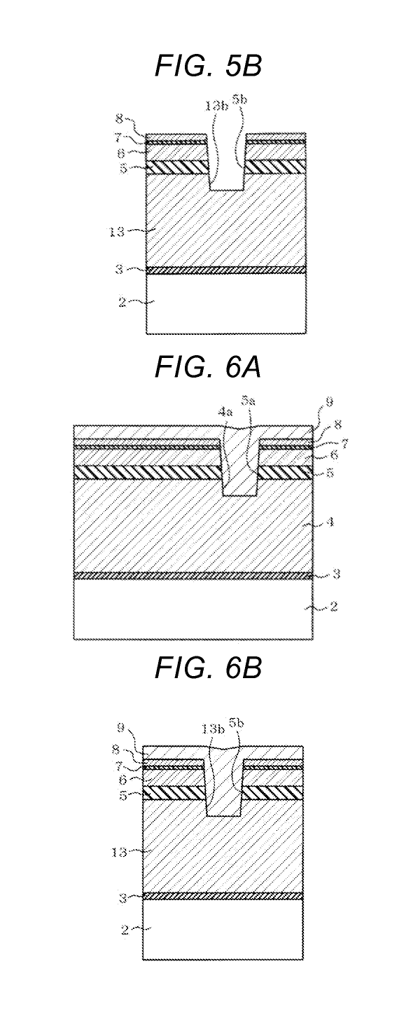

Next, as shown in FIGS. 5A and 5B, the opening 5a, the recess 4a, the opening 5b, and the recess 13b are formed in a position corresponding to the gate electrode SG of the selection gate transistor ST and in a position corresponding to the gate electrode PG of the transistor PT of the peripheral circuit, by a photolithography method. By etching the polycrystalline silicon film 8, the silicon oxide layer 7, the polycrystalline silicon film 6, and the inter-electrode insulating film 5, using a reactive ion etching (RIE) method, the openings 5a and 5b having a predetermined width dimension are formed, and the recesses 4a and 13b having a predetermined depth dimension are formed on the polycrystalline silicon films 4 and 13.

After performing the etching process, a cleaning process is performed to remove oxide films and the like formed on the surface of the polycrystalline silicon film 8 and the surfaces of the openings 5a and 5b and the recesses 4a and 13b. In the cleaning process, since the process is performed using a diluted hydrofluoric acid solution, exposed portions of the surface of the silicon oxide layer 7 may be etched and removed. In one embodiment, since the polycrystalline silicon film 8 is provided, so as to cover the upper surface of the silicon oxide layer 7, it is possible to protect the silicon oxide layer 7 from exposure to the cleaning solution, and therefore it is possible to prevent loss of the silicon oxide layer 7.

Next, as shown in FIGS. 6A and 6B, the non-doped polycrystalline silicon film 9 is formed with a predetermined film thickness to bury the upper surface of the polycrystalline silicon film 6 and the inside of the recess 4a. In this case, by setting the film thickness of the polycrystalline silicon film 9 to be larger than half of the width dimension of the opening 5a and the recess 4a, it is possible to suppress generation of a difference in level on the upper surface. In addition, in some embodiments, in order to solve the difference in level, the film is formed to have a film thickness larger than the half of the width dimension, and then an etching-back process can be performed after forming the film to reduce the surface level variation.

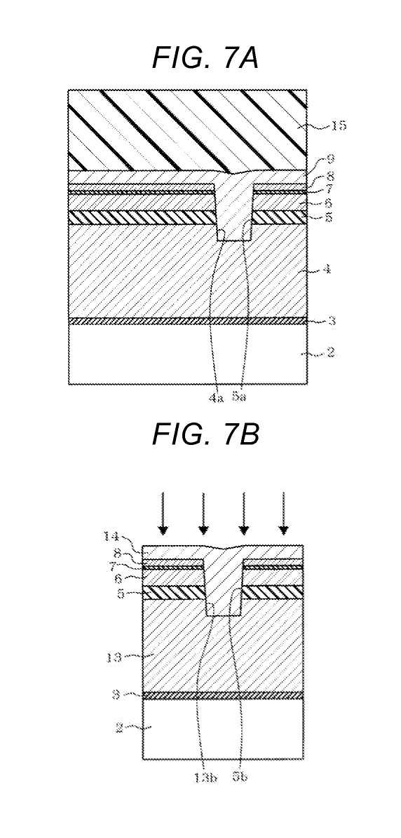

Next, as shown in FIGS. 7A and 7B, a resist film 15 is formed on the memory cell region side and the peripheral circuit region side is exposed. With the resist film 15 as a mask, the phosphorus (P) ions which are an N-type dopant are implanted into the polycrystalline silicon film 9 in the peripheral circuit region by an ion implantation method. After removing the resist film 15, the implanted phosphorus ions are activated by performing the heat treatment and the N-type polycrystalline silicon film 14 is formed. The heat treatment may not be performed immediately after implanting the ions. For example, the heat treatment may be performed at the same time as the heat treatment used to activate the diffusion region 2a.

During the heat treatment process after the ion implantation process is performed, boron which is the dopant in the polycrystalline silicon film 6, will tend to diffuse to the outside surface of the polycrystalline silicon film 6. In this case, if boron diffuses to the polycrystalline silicon film 14 in which the phosphorus (P) is doped in the peripheral circuit region, it is not preferable because the concentration of dopant which functions as a carrier is decreased and the electrical resistance is increased. However, it is possible to suppress the invasion of boron into the polycrystalline silicon film 14 by the silicon oxide layer 7 and the non-doped polycrystalline silicon film 8 formed on the upper surface of the polycrystalline silicon film 6.

The function of suppressing the movement of the dopant can be achieved by providing the silicon oxide layer 7. In addition, in the polycrystalline silicon film 8 as the protection layer, since grain boundary regions are formed on the boundary portions between the upper and lower films. The grain boundary regions exhibit the effect of suppressing the diffusion of the boron between the formed layers. As a result, the diffusion of the boron from the polycrystalline silicon film 6 into the polycrystalline silicon film 14, is only created at an end surface of the polycrystalline silicon film 6 which is exposed to the portion of the opening 5b. If the silicon oxide layer 7 and the polycrystalline silicon film 8 do not exist, the portion where the polycrystalline silicon film 6 comes in contact with the polycrystalline silicon film 14 is smaller in proportion to the upper surface of the polycrystalline silicon film 6, and thus will have a small amount of inter-diffusion. In such a case, the amount of the dopant that would have diffused from the upper surface of the polycrystalline silicon film 6 to the polycrystalline silicon film 14 is larger than the amount of the dopant diffused from the portion of the polycrystalline silicon film 6 exposed to the polycrystalline silicon film 14 in the opening 5b. As a result, according to this embodiment, it is possible to suppress an increase in resistance of the polycrystalline silicon film 13 buried in the opening 5b and the recess 13b.

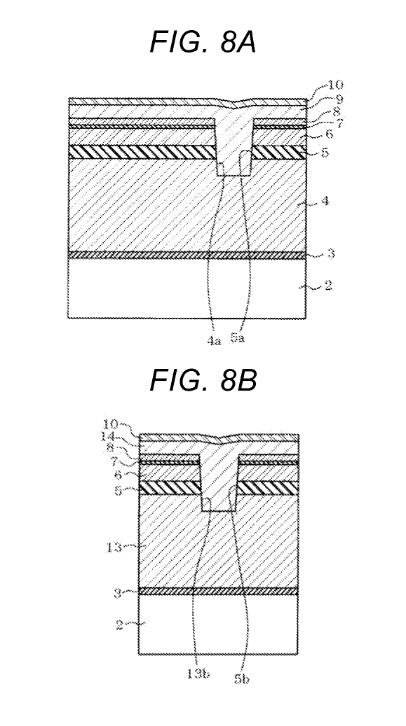

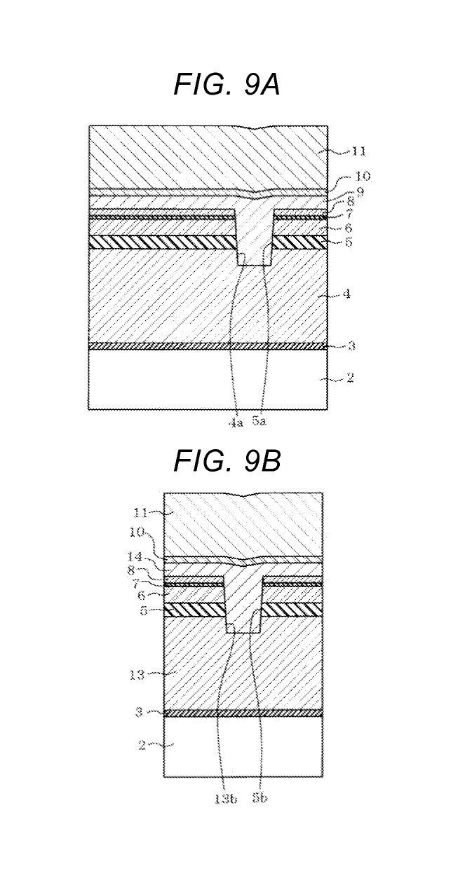

Next, as shown in FIGS. 8A, 8B, 9A, and 9B, the tungsten nitride (WN) film 10 and the tungsten film 11 are formed, in this order, on the upper surfaces of the polycrystalline silicon films 9 and 14 by a sputtering method. The tungsten nitride film 10 functions as a barrier metal film. Accordingly, the tungsten nitride film 10 is interposed between the tungsten nitride film 10 and the polycrystalline silicon films 9 and 14, and thus will tend to suppress a reaction created by the direct contact of the tungsten film 11 with the polycrystalline silicon films 9 and 14.

Subsequently, as shown in FIGS. 3A and 3B, gate processing is performed after forming the silicon nitride film 12 on the upper surface of the tungsten film 11 to form the gate electrodes MG, SG, and PG. During the gate forming process, with the silicon nitride film 12 being used as a hard mask, the tungsten film 11, the tungsten nitride film 10, the polycrystalline silicon films 9, 14, and 8, the silicon oxide layer 7, the polycrystalline silicon film 6, the inter-electrode insulating film 5, and the polycrystalline silicon films 4 and 13 are etched by an RIE method to separately form the gate electrodes MG, SG, and PG. After performing the gate processing, the dopant is implanted into the surface of the silicon substrate 2 between the gate electrodes MG and SG and the surface of the silicon substrate 2 on both sides of the gate electrode PG by the ion implantation, to form the diffusion regions 2a and 2b.

After that, although not shown in the drawings, an interlayer insulating film is formed to cover the upper surfaces of the gate electrodes MG and SG, and a contact or the like is formed to form the NAND-type flash memory device 1.

According to one embodiment, the silicon oxide layer 7 is provided on the upper surface of the P-type polycrystalline silicon film 6 which is formed on the upper surface of the inter-electrode insulating film 5. In another embodiment, the silicon oxide layer 7 and the polycrystalline silicon film 8 may be provided on the upper surface of the P-type polycrystalline silicon film 6. As a result, it is possible to suppress the invasion of boron which is the dopant in the polycrystalline silicon film 6 into the N-type polycrystalline silicon film 14, and possible to suppress an increase of the resistance value of the polycrystalline silicon film 14.

Since the non-doped polycrystalline silicon film 8 is provided on the upper surface of the silicon oxide layer 7, it is possible to protect the silicon oxide layer 7 during one or more processing steps (e.g., cleaning step), and possible to obtain an effect of suppressing the diffusion of the dopant by the grain boundary region which is formed on the upper surface of the silicon oxide layer 7 between the surface of the silicon oxide layer 7 and the non-doped polycrystalline silicon film 8.

### Second Embodiment

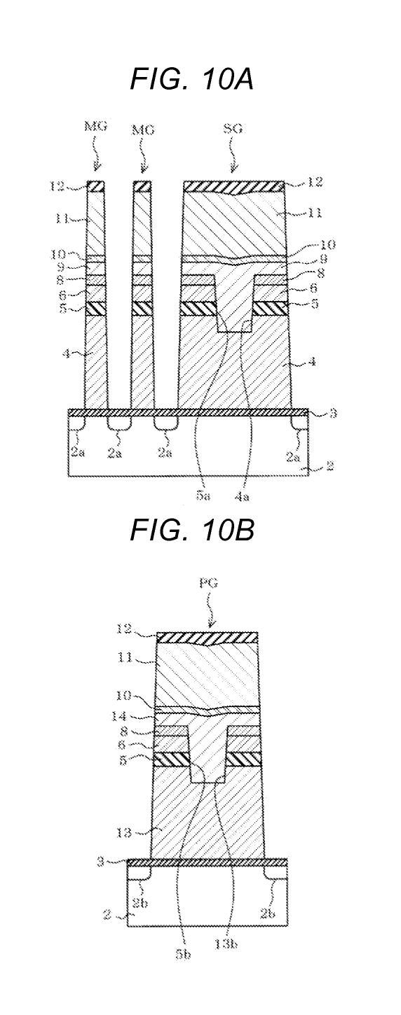

FIGS. 10A and 10B show another embodiment of the invention disclosed herein. In one embodiment, the silicon oxide layer 7 is not formed within the structure described above. That is, as shown in FIGS. 10A and 10B, the non-doped polycrystalline silicon film 8 is formed, so as to directly contact with the upper surface of the polycrystalline silicon film 6. Thus, in one embodiment, the barrier film may only comprise a polycrystalline silicon film, such as the non-doped polycrystalline silicon film 8.

In this case, silicon grain boundary regions are formed on boundary portions between the polycrystalline silicon films 6 and 8 and between the polycrystalline silicon films 8 and 14, respectively. As a result, the grain boundary regions can suppress the diffusion of boron. Accordingly, it is possible to suppress a decrease in concentration of carriers in the N-type polycrystalline silicon film 14, and it possible to prevent the increase in the resistance due to the diffusion of the P-type dopants into the N-type polycrystalline silicon film 14.

In the manufacturing process described above, after forming the polycrystalline silicon film 6 in which boron is doped as the P-type dopant, the non-doped polycrystalline silicon film 8 is subsequently formed without performing the oxidation treatment step. In this configuration, the polycrystalline silicon films 6, 8, and 14 are sequentially formed. However, since the grain boundary regions which terminate crystal grains are formed on boundary portions of each of the polycrystalline silicon films 6, 8, and 14, the grain boundary regions have an effect of preventing the dopant from diffusing between the formed layers.

Accordingly, in the second embodiment, even when the silicon oxide layer 7 is not provided, an effect of suppressing the invasion of boron into the N-type polycrystalline silicon film 14 can be obtained.

### Third Embodiment

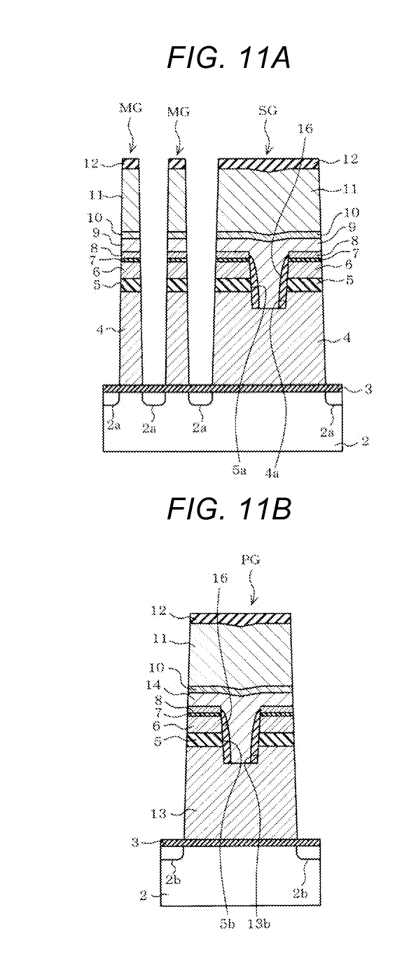

One embodiment of the invention disclosed herein is shown in FIGS. 11A to 14B. Hereinafter, the parts different from the first embodiment will be described.

In one embodiment, as shown in FIG. 11B, in addition to the configuration of the first embodiment, spacers 16 are formed so as to cover the side wall surfaces of the opening 5b and the recess 13b. The spacer 16 is formed with a silicon nitride film (SiN film), for example. It is possible to suppress the invasion of boron into the polycrystalline silicon film 14 from the end surface portion of the P-type polycrystalline silicon film 6 exposed in the opening 5b by the spacer 16. As a result, it is possible to suppress an increase in the p-type dopant concentration in the N-type polycrystalline silicon film 14 in the opening 5b and the recess 13b, and it is possible to prevent an increase in the electrical resistance therein.

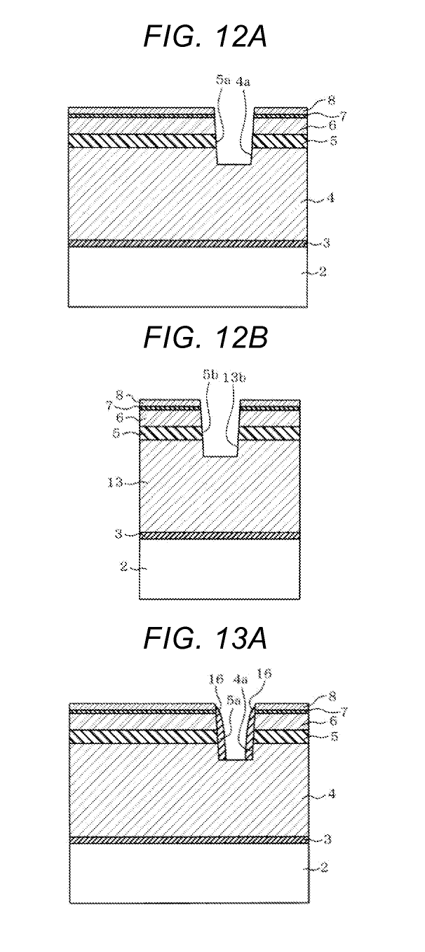

Next, a process of forming the spacer 16 will be described with reference to FIGS. 12A to 14B. The other parts of the forming process are the same as the first embodiment discussed above, and the description thereof will be omitted. FIGS. 12A and 12B show the same state as the state shown in FIGS. 5A and 5B of the first embodiment. That is, as shown in FIGS. 12A and 12B, the opening 5a, the recess 4a, the opening 5b, and the recess 13b are formed in a position corresponding to the gate electrode SG of the selection gate transistor ST and in a position corresponding to the gate electrode PG of the transistor PT of the peripheral circuit, by a photolithography process.

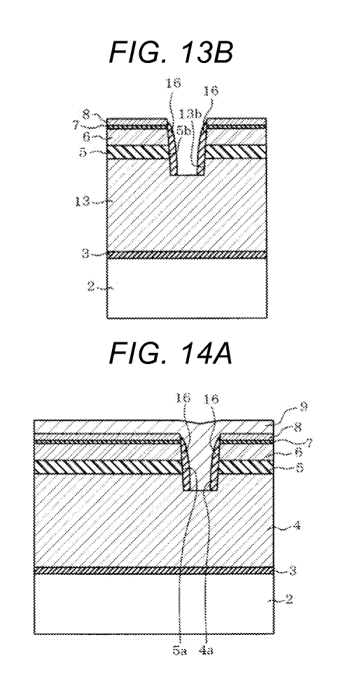

Next, as shown in FIGS. 13A and 13B, spacers 16, which may be formed of a silicon nitride film, are formed on the side wall portions of the openings 5a and 5b and the recesses 4a and 13b. The spacers 16 can be formed as follows. For example, the silicon nitride film can be formed on the entire surface of the upper surface of the configuration shown in FIGS. 12A and 12B. Then, by performing an etching-back process using an RIE method, the silicon nitride film is processed so as to expose the upper surface portion of the polycrystalline silicon film 8 and the bottom surface portion of the recesses 4a and 13b. Accordingly, the spacers 16 are formed on the side wall portions of the openings 5a and 5b and the recesses 4a and 13b. In this case, the spacers 16 are formed so that the upper end portion is located at a position from the upper surface to the intermediate portion of the polycrystalline silicon film 8, and so as to cover the end surface portion of the silicon oxide layer 7 exposed to the openings 5a and 5b.

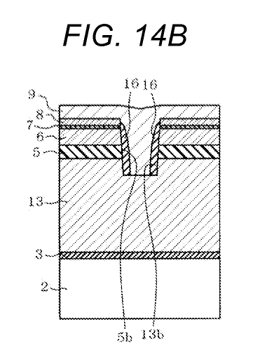

Next, as shown in FIGS. 14A and 14B, the non-doped polycrystalline silicon film 9 is formed with a predetermined film thickness, so as to bury the upper surface of the polycrystalline silicon film 6 and the inside of the recesses 4a and 13b. After that, in the same manner as the first embodiment, the step of implanting the phosphorus (P) ions into the polycrystalline silicon film 9 on the peripheral circuit region side to form the N-type polycrystalline silicon film 14 is performed and the NAND-type flash memory device is formed by performing the same manufacturing step.

According to the third embodiment, since the spacers 16 are formed on the side wall surfaces of the opening 5b and the recess 13b, in addition to the effect of the embodiments described above, it is possible to suppress the diffusion of boron from the end surface portion of the polycrystalline silicon film 6, which is exposed to the opening 5b, and it is possible to suppress the increase of the resistance value of the N-type polycrystalline silicon film 14.

The spacers 16 as the barrier side wall films are formed by the silicon nitride film, however a silicon oxide film or the other film may be used.

### OTHER EMBODIMENTS

The following modifications can be performed in addition to the embodiment described above.

Embodiments of the disclosure provided herein can be applied to the NAND-type flash memory device 1 and also be applied to a nonvolatile semiconductor memory device, such as a NOR-type flash memory device or an EEPROM and the like. In addition, the embodiment may be applied to a device in which a memory cell is configured as one bit or a plurality of bits.

For the dopant which is doped in the polycrystalline silicon film 6, the example of using boron (B) as the P-type dopant. However, another dopant may be used as long as it is a P-type dopant. In addition, the example of using the P type as the first conductivity type and the N type as the second conductivity type is shown. However the P type and the N type may be switched and used.

For the barrier film, in one embodiment, other than the silicon oxide layer 7, a silicon nitride layer obtained by performing a nitride treatment of the polycrystalline silicon film, or a composite layer of an oxide layer and a nitride layer may be formed. In addition, a configuration of forming the other film to function as a barrier film to suppress the movement of the dopant may be used. In another embodiment, the barrier film may comprise the silicon oxide layer 7 and a polysilicon film, such as the non-doped polycrystalline silicon film 8.

In addition to performing the oxidation treatment of the surface of the polycrystalline silicon film 6 to form the silicon oxide layer 7 to form the barrier film, the barrier film may also be formed and/or deposited on the upper surface of the polycrystalline silicon film 6 as a separate film.

The spacers 16 shown in the third embodiment can also be applied to any of the configuration described herein. In addition, the spacers thereof may be also applied to the configuration of the related art of not providing the silicon oxide layer 7 and the non-doped polycrystalline silicon film 8. In this case, boron easily flows to the N-type polycrystalline silicon film 14 from the upper surface of the P-type polycrystalline silicon film 6, however, since the spacers 16 are formed in the portion of the opening 5b and the recess 13b, it is possible to suppress direct invasion of boron, and accordingly, an effect of suppressing the increase of resistance in this portion is obtained.

In one embodiment, a gate electrode MG of the selection gate transistor SG is obtained by laminating a polycrystalline silicon film 4, a polycrystalline silicon film 6, a silicon oxide layer 7, a polycrystalline silicon film 8, a polycrystalline silicon film 9, a tungsten nitride (WN) film 10, a tungsten (W) film 11, and a silicon nitride film 12, in this order, on a gate insulating film 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell transistor comprising:
a first conductive film disposed above a first region of a substrate, and comprising a first conductivity type dopant;
an inter-electrode insulating film disposed on the first conductive film; and
a second conductive film disposed above the inter-electrode insulating film, and having the first conductivity type dopant; and
a peripheral circuit transistor comprising:
a third conductive film disposed above a second region of the substrate, and having a second conductivity type dopant, which is a type opposite to the first conductivity type;
the inter-electrode insulating film, which is disposed on the third conductive film;
a fourth conductive film disposed above the inter-electrode insulating film, and having the first conductivity type dopant;
a barrier film disposed above the fourth conductive film; and
a fifth conductive film disposed on the barrier film, and having the second conductivity type dopant,
wherein the peripheral circuit transistor has an opening formed through a portion of the barrier film, the fourth conductive film and the inter-electrode insulating film, that exposes a portion of the third conductive film, and
the fifth conductive film is formed so as to contact with the third conductive film via the opening.

2. The device according to claim 1, wherein the first conductivity type dopant is a P-type dopant and the second conductivity type dopant is an N-type dopant.

3. The device according to claim 1, wherein the barrier film includes a grain boundary region formed at an interface between the fourth conductive film and the barrier film.

4. The device according to claim 1, wherein the barrier film includes a silicon oxide layer.

5. The device according to claim 4, wherein the barrier film further includes a protective film disposed between the silicon oxide layer and the fifth conductive film.

6. The device according to claim 1, further comprising a barrier side wall film formed along a side wall portion of the opening.

7. A nonvolatile semiconductor memory device, comprising:
a selection gate transistor comprising:
a first conductive film disposed above a first region of a substrate, and having a first conductivity type dopant; and
a second conductive film disposed on the first conductive film, and comprising the first conductivity type dopant; and
a peripheral circuit transistor comprising:
a third conductive film disposed above a second region of the substrate, and having a second conductivity type dopant, which is a type opposite to the first conductivity type;
an inter-electrode insulating film, which is disposed on the third conductive film;
a fourth conductive film disposed above the inter-electrode insulating film, and comprising the first conductivity type dopant;
a barrier film disposed above the fourth conductive film; and
a fifth conductive film disposed on the barrier film, and comprising the second conductivity type dopant,
wherein the peripheral circuit transistor has an opening formed through a portion of the barrier film, the fourth conductive film and the inter-electrode insulating film, that exposes a portion of the third conductive film, and
the fifth conductive film is formed so as to contact with the third conductive film via the opening.

8. The device according to claim 7, wherein the first conductivity type dopant is a P-type dopant and the second conductivity type dopant is an N-type dopant.

9. The device according to claim 7, wherein the barrier film includes a grain boundary region formed at an interface between the fourth conductive film and the barrier film.

10. The device according to claim 7, wherein the barrier film includes a silicon oxide layer.

11. The device according to claim 10, wherein the barrier film includes a protective film disposed between the silicon oxide layer and the fifth conductive film.

12. The device according to claim 7, further comprising a barrier side wall film formed along a side wall portion of the opening.

13. A method of forming a nonvolatile semiconductor memory device, comprising:
forming a memory cell transistor, wherein forming the memory cell transistor comprises:
forming a first conductive film above a first region of a substrate, wherein the first conductive film has a first conductivity type dopant;
forming an inter-electrode insulating film on the first conductive film; and
forming a second conductive film above the inter-electrode insulating film, wherein the second conductive film has the first conductivity type dopant; and
forming a peripheral circuit transistor, wherein forming the peripheral circuit transistor comprises:
forming a third conductive film above a second region of the substrate, wherein the third conductive film has a second conductivity type dopant, which is a type opposite to the first conductivity type;
forming the inter-electrode insulating film on the third conductive film;
forming a fourth conductive film on the inter-electrode insulating film, wherein the fourth conductive film has the first conductivity type dopant; and
forming a barrier film above the fourth conductive film;
forming an opening formed in a portion of the peripheral circuit transistor, wherein forming the opening includes removing a portion of the barrier film, the fourth conductive film and the inter-electrode insulating film, and exposing a portion of the third conductive film; and
forming a fifth conductive film on the barrier film, wherein the fifth conductive film has the second conductivity type dopant, and the fifth conductive film is formed so as to contact with the third conductive film within the opening.

14. The method of claim 13, wherein the first conductivity type dopant is a P-type dopant and the second conductivity type dopant is an N-type dopant.

15. The method of claim 13, wherein forming the barrier film further comprises forming a silicon oxide layer.

16. The method of claim 13, wherein forming the barrier film comprises forming a polycrystalline silicon layer.

17. The method of claim 13, further comprising forming a barrier side wall film along a side wall portion of the formed opening.
